(19) United States
(12) Patent Application Publication
(10) Pub. No.: US 2025/0253174 A1
(43) Pub. Date: Aug. 7, 2025

(54) Substrate Processing Apparatus and Temperature Monitoring Method

(71) Applicant: Tokyo Electron Limited, Tokyo (JP)

(72) Inventor: Takahiro KAWAWA, Yamanashi (JP)

(21) Appl. No.: 19/037,067

(22) Filed: Jan. 24, 2025

(30) Foreign Application Priority Data
Feb. 6, 2024 (JP) 2024-016112

(51) Int. Cl. H01L 21/67; G01K 7/04

(52) U.S. Cl. CPC H01L 21/67248; G01K 7/04

(57) ABSTRACT

There is a substrate processing apparatus comprising: a rotatable stage; a plurality of temperature sensors arranged on the stage in a distributed manner; a conversion part that processes signals outputted from each of the plurality of temperature sensors; and a switching part that switches the temperature sensor connected to the conversion part, the switching part includes: a plurality of electrode parts having electrodes, that are provided in one-to-one correspondence with the plurality of temperature sensors, arranged side by side along a rotation direction of the stage, and connected to the respective corresponding temperature sensors; and a contact part having a contactor, that is fixed to the stage, brought into contact with the electrode of one of the plurality of electrode parts at a time, and connected to the conversion part.

### CROSS-REFERENCE TO RELATED APPLICATIONS

This application claims priority to Japanese Patent Application No. 2024-016112 filed on Feb. 6, 2024, the entire contents of which are incorporated herein by reference.

### TECHNICAL FIELD

The present disclosure relates to a substrate processing apparatus and a temperature monitoring method.

### BACKGROUND

Japanese Laid-open Patent Publication No. 2011-222931 discloses a processing apparatus having a placing table structure. Japanese Laid-open Patent Publication No. 2011-222931 discloses that the processing apparatus includes, at the main body of the placing table, an inner peripheral zone heating element on the central side of the placing table and an outer peripheral zone heating element outside the inner peripheral zone heating element.

Japanese Laid-open Patent Publication No. 2005-136025 discloses a semiconductor manufacturing apparatus in which a wafer is held on a wafer stage by electrostatic attraction. Japanese Laid-open Patent Publication No. 2005-136025 discloses that the wafer stage is divided into multiple adhesion areas, and that a temperature of a wafer is measured by a fluorescent thermometer provided in each adhesion area.

### SUMMARY

The present disclosure provides a technique for measuring temperatures at multiple locations on a rotating stage.

In accordance with an exemplary embodiment of the present disclosure, there is a substrate processing apparatus comprising: a rotatable stage; a plurality of temperature sensors arranged on the stage in a distributed manner; a conversion part that processes signals outputted from each of the plurality of temperature sensors; and a switching part that switches the temperature sensor connected to the conversion part, the switching part includes: a plurality of electrode parts having electrodes, that are provided in one-to-one correspondence with the plurality of temperature sensors, arranged side by side along a rotation direction of the stage, and connected to the respective corresponding temperature sensors; and a contact part having a contactor, that is fixed to the stage, brought into contact with the electrode of one of the plurality of electrode parts at a time, and connected to the conversion part.

### BRIEF DESCRIPTION OF THE DRAWINGS

FIG. 1 schematically shows a substrate processing apparatus according to a first embodiment during rotation of a stage.

FIG. 2 schematically shows the substrate processing apparatus according to the first embodiment during cooling of the stage.

FIG. 3 is a plan view schematically showing measurement areas and the arrangement of temperature sensors on the stage of the substrate processing apparatus according to the first embodiment.

FIG. 4 is a partial cross-sectional view schematically showing the arrangement of electrode parts on the stage of the substrate processing apparatus according to the first embodiment.

FIG. 5 is a cross-sectional view schematically showing the arrangement of the electrode parts on the stage of the substrate processing apparatus according to the first embodiment.

FIG. 6 explains the connection of the temperature sensors in the substrate processing apparatus according to the first embodiment.

FIG. 7 is a (first) diagram explaining the connected temperature sensors in the substrate processing apparatus according to the first embodiment.

FIG. 8 is a (second) diagram explaining the connected temperature sensors in the substrate processing apparatus according to the first embodiment.

FIG. 9 is a (third) diagram explaining the connected temperature sensors in the substrate processing apparatus according to the first embodiment.

FIG. 10 is a plan view schematically showing measurement areas and the arrangement of temperature sensors on a stage of a substrate processing apparatus according to a second embodiment.

FIG. 11 is a partial cross-sectional view schematically showing the arrangement of electrode parts on a stage of a substrate processing apparatus according to a third embodiment.

FIG. 12 explains the connection of temperature sensors in a substrate processing apparatus according to the third embodiment.

### DETAILED DESCRIPTION

Hereinafter, embodiments will be described in detail with reference to the accompanying drawings. Further, the present disclosure is not limited to these examples, but is indicated by the scope of claims and is intended to include all modifications within the meaning and scope equivalent to the claims.

Further, in the description of the specification and drawings relating to each embodiment, like or corresponding reference numerals may be used for components having substantially the same or corresponding functional configurations to omit redundant description. Further, for ease of understanding, the scale of individual components in the drawings may be different from the actual scale.

### First Embodiment

A substrate processing apparatus according to a first embodiment will be described. The substrate processing apparatus according to the first embodiment includes a rotating stage, a plurality of temperature sensors arranged on the stage in a distributed manner, a conversion part that processes signals outputted from each of the plurality of temperature sensors, and a switching part that switches the temperature sensor connected to the conversion part. The switching part of the substrate processing apparatus according to the first embodiment includes a plurality of electrode parts having electrodes that are provided in one-to-one correspondence with the plurality of temperature sensors, arranged side by side along the rotation direction of the stage, and connected to the respectively corresponding temperature sensors. Further, the switching part of the substrate processing apparatus according to the first embodiment includes a contact part having a contactor that is fixed to the stage, and brought into contact with one electrode of the plurality of electrode parts at a time, and connected to the conversion part.

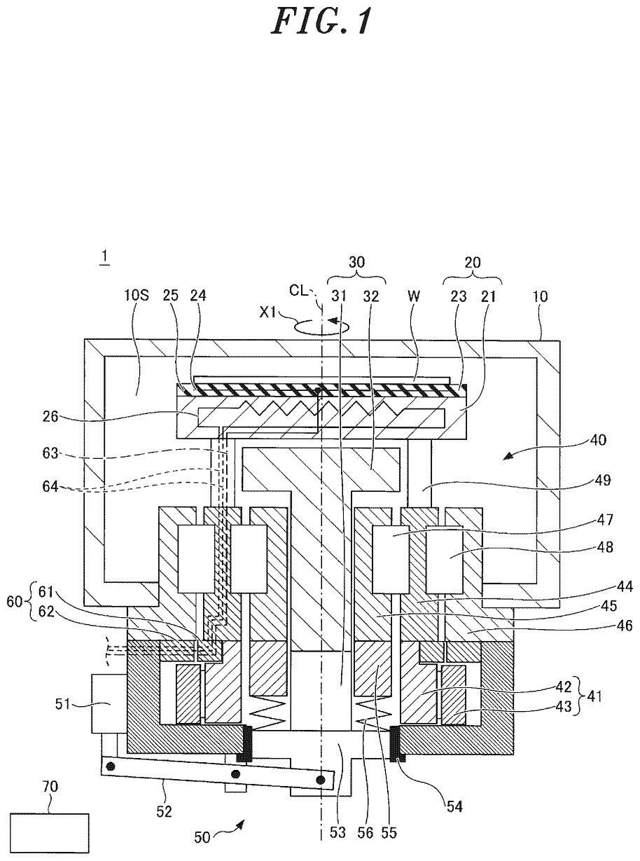

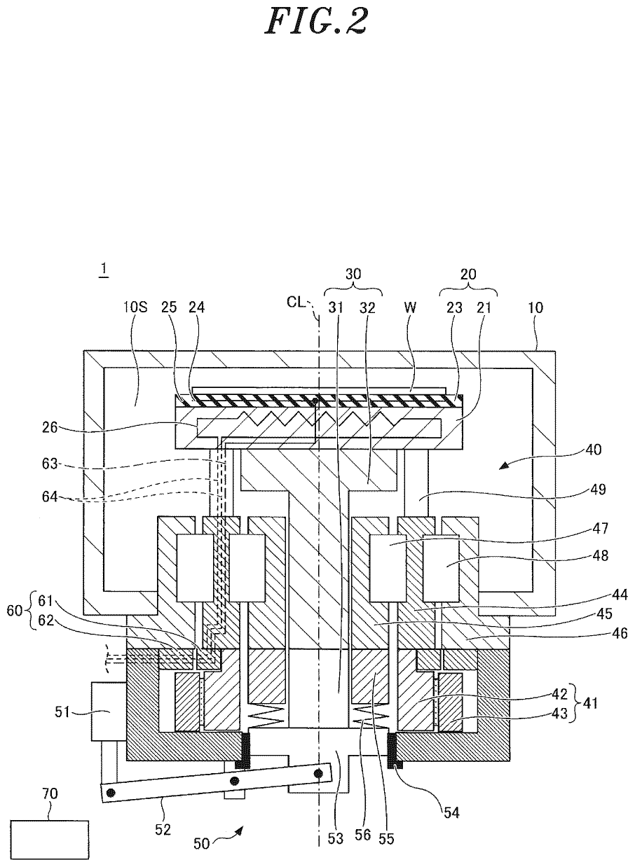

The substrate processing apparatus according to the first embodiment will be described in detail with reference to the drawings. FIG. 1 schematically shows a substrate processing apparatus 1, which is an example of the substrate processing apparatus according to the first embodiment, during rotation of a stage 20. FIG. 2 schematically shows the substrate processing apparatus 1, which is an example of the substrate processing apparatus according to the first embodiment, during cooling of the stage 20.

The substrate processing apparatus 1 may be, e.g., a substrate processing apparatus that supplies a processing gas into a processing chamber 10 to performs desired processing (e.g., film formation or the like) on a substrate W. The substrate processing apparatus 1 may be, e.g., a chemical vapor deposition (CVD) apparatus, an atomic layer deposition (ALD) apparatus, or the like. The substrate processing apparatus 1 may be, e.g., a substrate processing apparatus that supplies a processing gas into the processing chamber 10 and sputters a target provided in the processing chamber 10 to perform desired processing (e.g., film formation or the like) on the substrate W. The substrate processing apparatus 1 may be, e.g., a physical vapor deposition (PVD) apparatus, or the like. The substrate processing apparatus 1 heats or cools the substrate W to a desired temperature.

The substrate processing apparatus 1 includes the processing chamber 10, the stage 20 on which the substrate W is placed in the processing chamber 10, a freezing device 30, a rotation device 40 for rotating the stage 20, and a lifting device 50 for raising and lowering the freezing device 30. The substrate processing apparatus 1 further includes a slip ring 60 for supplying a power to the chuck electrode 24 and a heating part 26 of the stage 20 that is rotating. The substrate processing apparatus 1 further includes a controller 70 for controlling various devices such as the freezing device 30, the rotation device 40, and the lifting device 50.

The processing chamber 10 defines an inner space 10S. The processing chamber 10 is configured such that the inner space 10S can be depressurized to an ultra-high vacuum by operating an exhaust device (not shown) such as a vacuum pump or the like. Further, a desired gas used for substrate processing is supplied to the processing chamber 10 through gas supply line (not shown) communicating with a processing gas supply device (not shown).

The substrate processing apparatus 1 includes the stage 20 on which a substrate W is placed in the processing chamber 10. The stage 20 includes a base portion 21 and an electrostatic chuck 23.

The base portion 21 is made of a material having high thermal conductivity (e.g., copper (Cu)). The base portion 21 has therein a heating portion 26, e.g., an electric heater. A power is supplied to the heating portion 26 via the slip ring 60 and a wiring 64 that will be described later. The heating portion 26 to which the power is supplied heats the base portion 21. The electrostatic chuck 23 is heated by heating the base portion 21. The substrate W attracted to the electrostatic chuck 23 is heated by heating the electrostatic chuck 23.

The electrostatic chuck 23 is provided on the upper surface of the base portion 21. The electrostatic chuck 23 has a chuck electrode 24 embedded in a dielectric film 25. A predetermined potential is applied to the chuck electrode 24 via the slip ring 60 and the wiring 63 that will be described later. With this configuration, the substrate W can be attracted by the electrostatic chuck 23 and fixed to the upper surface of the stage 20.

The substrate processing apparatus 1 includes the freezing device 30 disposed below the stage 20. The freezing device 30 is formed by stacking a refrigerator 31 and a refrigeration medium 32. The refrigeration medium 32 can also be referred to as “cold link.” The refrigerator 31 holds the refrigeration medium 32, and cools the upper surface of the refrigeration medium 32 to an extremely low temperature. In view of cooling performance, the refrigerator 31 preferably uses a Gifford-McMahon (GM) cycle. The refrigeration medium 32 is fixed on the refrigerator 31. The upper part of the refrigeration medium 32 is accommodated in the processing chamber 10. The refrigeration medium 32 is made of a material having high thermal conductivity (e.g., copper (Cu)). The refrigeration medium 32 has a substantially cylindrical outer shape. The refrigeration medium 32 is disposed such that the center thereof coincides with a central axis CL of the stage 20.

As will be described later, in the substrate processing apparatus 1, the stage 20 is provided with a plurality of temperature sensors.

Further, the stage 20 is rotatably supported by the rotation device 40. The stage 20 rotates by the rotation device 40. The rotation device 40 includes a rotation driving device 41, a fixed shaft 45, a rotation shaft 44, a housing 46, magnetic fluid seals 47 and 48, and a stand 49.

The rotation driving device 41 is a direct drive motor having a rotor 42 and a stator 43. The rotor 42 has a substantially cylindrical shape extending coaxially with the rotation shaft 44, and is fixed to the rotation shaft 44. The stator 43 has a substantially cylindrical shape with an inner diameter greater than the outer diameter of the rotor 42. The rotation driving device 41 may be in a form other than a direct drive motor, and may be in a form including a servo motor and a transmission belt.

The rotation shaft 44 has a substantially cylindrical shape extending coaxially with the center axis CL of the stage 20. The fixed shaft 45 is provided inside the rotation shaft 44 in a radial direction. The fixed shaft 45 has a substantially cylindrical shape extending coaxially with the center axis CL of the stage 20. A housing 46 is provided outside the rotation shaft 44 in the radial direction. The housing 46 has a substantially cylindrical shape extending coaxially with the central axis CL of the stage 20, and is fixed to the processing chamber 10.

The magnetic fluid seal 47 is provided between the outer circumferential surface of the fixed shaft 45 and the inner circumferential surface of the rotation shaft 44. The magnetic fluid seal 47 rotatably supports the rotation shaft 44 with respect to the fixed shaft 45, and seals the gap between the outer circumferential surface of the fixed shaft 45 and the inner circumferential surface of the rotation shaft 44 to separate the inner space 10S of the depressurizable processing chamber 10 from the outer space of the processing chamber 10. The magnetic fluid seal 48 is provided between the inner circumferential surface of the housing 46 and the outer circumferential surface of the rotation shaft 44. The magnetic fluid seal 48 rotatably supports the rotation shaft 44 with respect to the housing 46, and seals the gap between the inner circumferential surface of the housing 46 and the outer circumferential surface of the rotation shaft 44 to separate the inner space 10S of the depressurizable processing chamber 10 from the outer space of the processing chamber 10. Accordingly, the rotation shaft 44 is rotatably supported by the fixed shaft 45 and the housing 46.

Further, the refrigeration medium 32 is inserted into the radially inner side of the fixed shaft 45.

The stand 49 is provided between the rotation shaft 44 and the stage 20, and is configured to transmit the rotation of the rotation shaft 44 to the stand 49.

With the above configuration, when the rotor 42 of the rotation driving device 41 rotates, the rotation shaft 44, the stand 49, and the stage 20 rotate relative to the refrigeration medium 32 in the X1 direction.

Further, the freezing device 30 is supported by the lifting device 50 to be vertically movable. The lifting device 50 includes an air cylinder 51, a link mechanism 52, a freezing device support 53, a linear guide 54, a fixed part 55, and a bellows 56.

The air cylinder 51 is a mechanical device whose rod moves linearly by air pressure. The link mechanism 52 converts the linear motion of the rod of the air cylinder 51 into the vertical motion of the freezing device support 53. Further, the link mechanism 52 has a lever structure, one end of which is connected to the air cylinder 51 and the other end of which is connected to the freezing device support 53. Accordingly, a large pressing force can be generated with a small thrust of the air cylinder 51. The freezing device support 53 supports the freezing device 30 (the refrigerator 31 and the refrigeration medium 32). Further, the moving direction of the freezing device support 53 is guided in the vertical direction by the linear guide 54.

The fixed part 55 is fixed to the bottom surface of the fixed shaft 45. The substantially cylindrical bellows 56 surrounding the refrigerator 31 is provided between the bottom surface of the fixed part 55 and the upper surface of the freezing device support 53. The bellows 56 is a metal bellows structure that is vertically extensible and contractible. Accordingly, the fixed part 55, the bellows 56, and the freezing device support 53 seal the gap between the inner circumferential surface of the fixed shaft 45 and the outer circumferential surface of the refrigeration medium 32 to separate the inner space 10S of the depressurizable processing chamber 10 from the outer space of the processing chamber 10. Further, the bottom surface side of the freezing device support 53 is adjacent to the outer space of the processing chamber 10, and the region surrounded by the bellows 56 on the upper surface side of the freezing device support 53 is adjacent to the inner space 10S of the processing chamber 10.

The slip ring 60 is provided below the rotation shaft 44 and the housing 46. The slip ring 60 has a rotating body 61 including a metal ring and a fixed body 62 including a brush. The rotating body 61 has a substantially cylindrical shape extending coaxially with the rotation shaft 44, and is fixed to the bottom surface of the rotation shaft 44. The fixed body 62 has a substantially cylindrical shape with an inner diameter slightly larger than an outer diameter of the rotating body 61, and is fixed to the bottom surface of the housing 46. The slip ring 60 is electrically connected to a DC power supply (not shown), and supplies a power from the DC power supply to the wiring 63 via the brush of the fixed body 62 and the metal ring of the rotating body 61. Further, the slip ring 60 is electrically connected to a heating power supply (not shown), and supplies a power from the heating power supply to the wiring 63 via the brush of the fixed body 62 and the metal ring of the rotating body 61. With this configuration, a potential can be applied from the DC power supply to the chuck electrode 24 without twisting the wiring 63. Further, the power can be supplied from the heating power supply to the heating part 26. The structure of the slip ring 60 may be a structure other than the brush structure, for example, a contactless power supply structure, a mercury-free structure, a structure containing a conductive liquid, or the like.

As will be described later, the substrate processing apparatus 1 includes a switching part between the rotation shaft 44 and the housing 46.

The controller 70 is, e.g., a computer, and includes a central processing unit (CPU), a random access memory (RAM), a read only memory (ROM), an auxiliary storage device, and the like. The CPU operates based on a program stored in the ROM or the auxiliary storage device to controls the operation of the substrate processing apparatus 1. The controller 70 may be installed inside the substrate processing apparatus 1, or may be installed outside the substrate processing apparatus 1. When the controller 70 is provided outside the substrate processing apparatus 1, the controller 70 can control the substrate processing apparatus 1 using a wired or wireless communication device.

In the case of performing desired processing on the substrate W, as shown in FIG. 1, the controller 70 controls the lifting device 50 (the air cylinder 51) to separate the stage 20 from the refrigeration medium 32, and controls the rotation device 40 (the rotation driving device 41) to rotate the stage 20 on which the substrate W is placed. Accordingly, the in-plane uniformity of the substrate processing (e.g., film formation or the like) of the substrate W can be improved.

Further, in the case of cooling the stage 20 and the substrate W placed on the stage 20, as shown in FIG. 2, the controller 70 stops the rotation device 40 (the rotation driving device 41) to stop the rotation of the stage 20, and controls the lifting device 50 (the air cylinder 51) to bring the stage 20 and the refrigeration medium 32 into contact with each other. Accordingly, the substrate W placed on the stage 20 can be cooled.

Here, if the pressing force for pressing the refrigeration medium 32 against the stage 20 is insufficient, loss occurs in heat conduction, and the cooling performance for the stage 20 is insufficient.

On the other hand, in the substrate processing apparatus 1, the upper surface (contact surface) of the refrigeration medium 32 is in direct contact with the bottom surface (surface to be contacted) of the stage 20, and the refrigeration medium 32 is brought into contact with the stage 20 and stops. Accordingly, the refrigeration medium 32 is in direct contact with the stage 20, so that the cooling performance for the stage 20 can be improved.

Further, by depressurizing the inner space 10S of the processing chamber 10 to a vacuum atmosphere, a pressure difference (vacuum pressure difference) is generated between the upper surface of the freezing device support 53 in a vacuum atmosphere and the bottom surface of the freezing device support 53 in an air atmosphere, which generates a pressing force for pressing the refrigeration medium 32 against the stage 20. Therefore, the pressing force is applied to the refrigeration medium 32 by the thrust of the air cylinder 51 and the pressure difference (vacuum pressure difference) generated between the upper surface and the bottom surface of the freezing device support 53. Accordingly, when the refrigeration medium 32 is brought into contact with the placing table 20 to cool the placing table 20, even if the placing table 20 is thermally contracted, the refrigeration medium 32 may be raised to correspond to the thermal contraction of the placing table 20 by the pressing force.

Further, the vertical movement of the refrigeration medium 32 is guided by the freezing device support 53 and the linear guide 54. Accordingly, the refrigeration medium 32 can be raised and lowered in a state where the bottom surface (the surface to be contacted) of the placing table 20 and the upper surface (the contact surface) of the refrigeration medium 32 are maintained to be parallel to each other.

Further, a shim (not shown) is inserted into the refrigeration medium 32 to adjust a degree of parallel of the upper surface (the contact surface) of the refrigeration medium 32 with respect to the bottom surface (the surface to be contacted) of the placing table 20.

Further, since the air cylinder 51 that is driven by air is used, the pressing force can be easily adjusted using an air pressure.

Further, in the case of heating the stage 20 and the substrate W placed on the stage 20, the controller 70 supplies a power to the heating part 26 to heat the stage 20 and the substrate W placed on the stage 20.

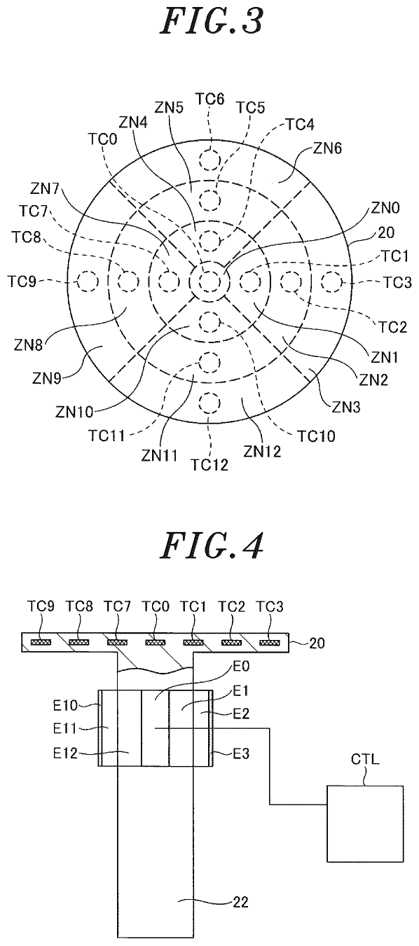

Next, the arrangement of temperature sensors and temperature measurement zones on the stage of the substrate processing apparatus according to the first embodiment will be described. FIG. 3 is a plan view schematically showing the arrangement of temperature sensors and measurement zones on the stage 20 of the substrate processing apparatus 1 that is an example of the substrate processing apparatus according to the first embodiment.

The substrate processing apparatus 1 includes a plurality of temperature sensors, specifically, thirteen temperature sensors in total, on the stage 20. More specifically, the substrate processing apparatus 1 includes temperature sensors TC0 to TC12. The plurality of temperature sensors are distributed and arranged in the stage 20. Further, the number of temperature sensors is not limited to thirteen. The number of temperature sensors may be appropriately determined based on the number of locations to be measured.

Each of the temperature sensors TC0 to TC12 is, e.g., a thermocouple. The thermocouple is, e.g., a K-type thermocouple made of an alloy that is mainly nickel and chromium and an alloy that is mainly nickel and aluminum. The type of thermocouple is not limited to the above example.

Further, each of the temperature sensors TC0 to TC12 is not limited to a thermocouple. For example, each of the temperature sensors TC0 to TC12 may be a resistance temperature detector.

In FIG. 3, the substrate processing apparatus 1 includes the temperature sensor TC0 at the center of the stage 20. The substrate processing apparatus 1 has a measurement zone ZN0 around the temperature sensor TC0 on the stage 20. The temperature sensor TC0 measures the temperature in the measurement zone ZN0. The measurement zone ZN0 has a circular shape in plan view.

Further, in FIG. 3, the substrate processing apparatus 1 includes the temperature sensors TC1, TC2, and TC3 sequentially arranged from the inner side on the right side of the temperature sensor TC0. The substrate processing apparatus 1 has the measurement zones ZN1, ZN2, and ZN3 around the temperature sensors TC1, TC2, and TC3 on the stage 20, respectively. The temperature sensors TC1, TC2, and TC3 measure the temperatures in the measurement zones ZN1, ZN2, and ZN3, respectively. Each of measurement zones ZN1, ZN2, and ZN3 has a shape that is a part of a ring body in plan view.

Further, in FIG. 3, the substrate processing apparatus 1 includes the temperature sensors TC4, TC5, and TC6 sequentially arranged from the inner side at a position above the temperature sensor TC0. The substrate processing apparatus 1 has the measurement zones ZN4, ZN5, and ZN6 around the temperature sensors TC4, TC5, and TC6 on the stage 20, respectively. The temperature sensors TC4, TC5, and TC6 measure the temperatures in the measurement zones ZN4, ZN5, and ZN6, respectively. Each of the measurement zones ZN4, ZN6, and ZN6 has a shape that is a part of a ring body in plan view.

Further, in FIG. 3, the substrate processing apparatus 1 includes the temperature sensors TC7, TC8, and TC9 sequentially arranged from the inner side on the left side of the temperature sensor TC0. The substrate processing apparatus 1 has THE measurement zones ZN7, ZN8, and ZN9 around the temperature sensors TC7, TC8, and TC9 on the stage 20, respectively. The temperature sensors TC7, TC8, and TC9 measure the temperatures in the measurement zones ZN7, ZN8, and ZN9, respectively. Each of the measurement zones ZN7, ZN9, and ZN9 has a shape that is a part of a ring body in plan view.

Further, in FIG. 3, the substrate processing apparatus 1 includes the temperature sensors TC10, TC11, and TC12 sequentially arranged from the inner side at a position below the temperature sensor TC0. The substrate processing apparatus 1 has the measurement zones ZN10, ZN11, and ZN12 around temperature sensors TC10, TC11, and TC12 on stage 20, respectively. The temperature sensors TC10, TC11, and TC12 measure the temperatures in the measurement zones ZN10, ZN11, and ZN12, respectively. Each of the measurement zones ZN10, ZN11, and ZN12 has a shape that is a part of a ring body in plan view.

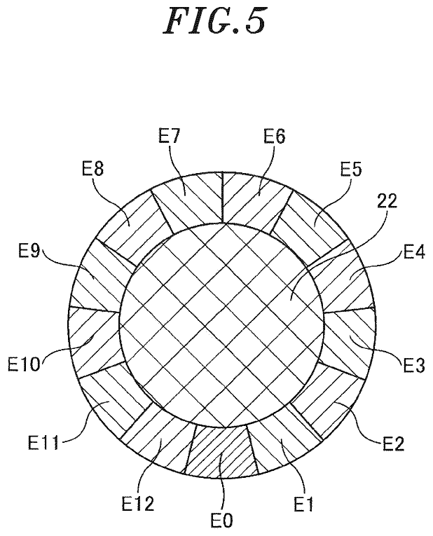

Next, the connection between the temperature sensors and the electrode parts in the substrate processing apparatus according to the first embodiment will be described. FIG. 4 is a partial cross-sectional view schematically showing the arrangement of the electrode parts on the stage 20 of the substrate processing apparatus 1 that is an example of the substrate processing apparatus according to the first embodiment. FIG. 5 is a cross-sectional view schematically showing the arrangement of the electrode parts on the stage 20 of the substrate processing apparatus 1 that is an example of the substrate processing apparatus according to the first embodiment. In FIG. 4, the rotation shaft 44 and the stand 49 in FIG. 1 are collectively illustrated as a rotation body 22. Further, the electrode parts are provided at the rotation shaft 44. In FIG. 5, the rotation body 22 is not illustrated in detail, and is indicated by hatching.

The substrate processing apparatus 1 includes electrode parts E0 to E12 corresponding to the temperature sensors TC0 to TC12, respectively. The temperature sensor TC0 is connected to the electrode part E0. Similarly, the temperature sensors TC1 to TC12 are connected to the corresponding electrodes E1 to E12, respectively.

The substrate processing apparatus 1 includes electrode parts arranged side by side in the rotation direction of the stage 20. The electrode parts rotate together with the stage 20. The substrate processing apparatus 1 includes the electrode part E0 on the lower side in FIG. 5. The substrate processing apparatus 1 includes the electrode parts E1 to E12 in a counterclockwise direction from the electrode part E0.

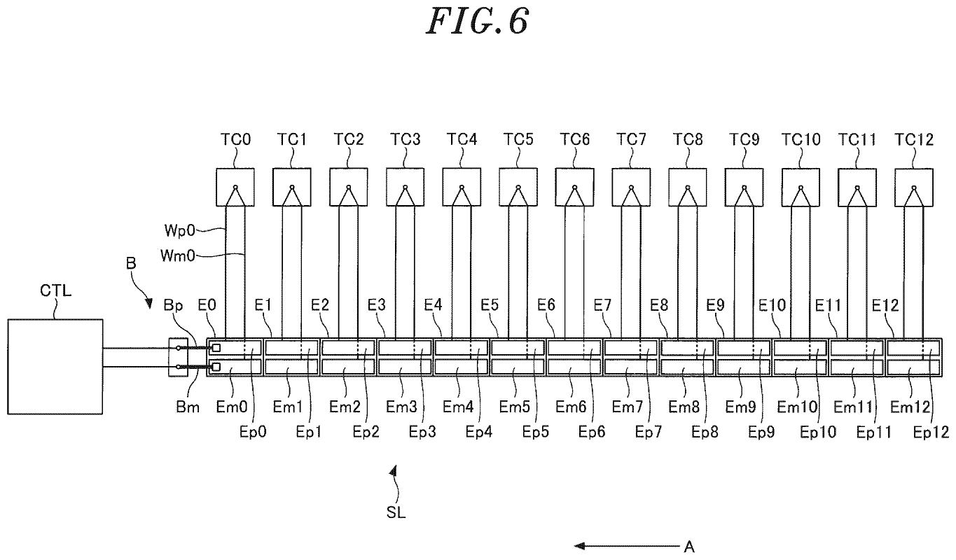

Next, the connection of the temperature sensors in the substrate processing apparatus according to the first embodiment will be described. FIG. 6 explains the connection of the temperature sensors in the substrate processing apparatus 1 that is an example of the substrate processing apparatus according to the first embodiment.

A switching part SL includes the plurality of electrode parts (the electrode parts E0 to E12) and a contact part B. The switching part SL switches the temperature sensor (the temperature sensors TC0 to TC12) to be connected to a conversion part CTL.

The conversion part CTL processes the signal outputted from/by the temperature sensor (any one of the temperature sensors TC0 to TC12). The conversion part CTL measures the temperature on the stage 20 by processing the signal outputted from/by the temperature sensor (any one of the temperature sensors TC0 to TC12).

Further, the conversion part CTL is implemented in the controller 70, for example.

The temperature sensor in the substrate processing apparatus 1 has, e.g., two wires. If the temperature sensor in the substrate processing apparatus 1 is, e.g., a thermocouple, the temperature sensor TC0, for example, has a positive wire Wp0 and a negative wire Wm0. For example, the temperature sensor TC0 measures the temperature by the thermoelectromotive force between the positive wire Wp0 and the negative wire Wm0. The electrode part E0 has a positive electrode Ep0 and a negative electrode Em0. The positive wire Wp0 is connected to the positive electrode Ep0 in the electrode part E0. The negative wire Wm0 is connected to the negative electrode Em0 in the electrode part E0.

Similarly to the electrode part E0, the electrode part E1 has a positive electrode Ep1 and a negative electrode Em1. Similarly, each of electrode parts E2 to E12 has any one of the corresponding positive electrodes Ep2 to Ep12 and any one of the corresponding negative electrodes Em2 to Em12.

The substrate processing apparatus 1 includes a contact part B having a positive contactor bp and a negative contactor bm. The contact part B is connected to any one of the electrode parts E0 to E12. The positive contactor bp and negative contactor bm are, e.g., conductive brushes. Specifically, the positive contactor bp and the negative contactor bm in the contact part B are connected to the positive electrode and the negative electrode of any one of the electrode parts E0 to E12 connected to the contact part B, respectively. For example, when the contact part B is connected to the electrode part E0, the positive contactor Bp and the negative contactor Bm in the contact part B are connected to the positive electrode Ep0 and the negative electrode Em0, respectively.

For example, in FIG. 3, when the stage 20 rotates in a clockwise direction, the electrode parts E0 to E12 move in the direction of arrow A in FIG. 6. Therefore, in the contact part B, the positive contactor Bp is sequentially brought into contact with the positive electrodes Ep0 to Ep12. Similarly, the negative contactor Bm is sequentially brought into contact with the negative electrodes Em0 to Em12. When the stage 20 further rotates in a clockwise direction and the electrode parts E0 to E12 move in the direction of the arrow A in a state where the positive contactor bp is in contact with the positive electrode Ep12 and the negative contactor bm is in contact with the negative electrode Em12, the positive contactor bp is brought into contact with the positive electrode Ep0 and the negative contactor bm is brought into contact with the negative electrode Em0, thereby repeating the contact.

Further, in FIG. 3, when the stage 20 rotates in a counterclockwise direction, the electrode parts E0 to E12 move in the opposite direction of the arrow A.

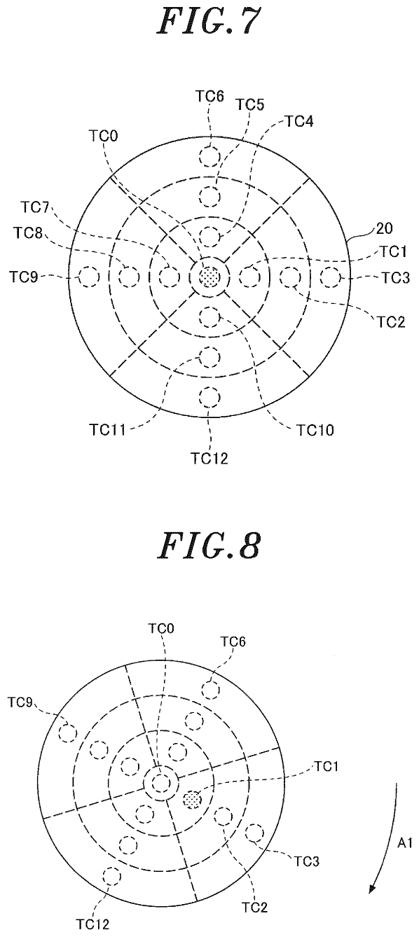

The operation of switching the temperature sensor to be detected in the substrate processing apparatus according to the first embodiment will be described. A temperature monitoring method in the substrate processing apparatus according to the first embodiment will be described by explaining the operation of switching the temperature sensor to be detected in the substrate processing apparatus according to the first embodiment. Each of FIGS. 7 to 9 explains the temperature sensors connected to the conversion part CTL in the substrate processing apparatus 1 that is an example of the substrate processing apparatus according to the first embodiment. Further, in each of FIGS. 7 to 9, the temperature sensors connected to the conversion part CTL are indicated by dot patterns.

First, it is assumed that the temperature sensor TC0 and the conversion part CTL are connected as shown in FIG. 7. In the state shown in FIG. 7, the contact part B of the switching part SL is connected to the electrode E0. When the contact part B of the switching part SL is connected to the electrode part E0, the switching part SL connects the temperature sensor TC0 and the conversion part CTL.

When the stage 20 is rotated in a clockwise direction by an angle of 30 degrees as indicated by an arrow A1 in FIG. 8, the contact part B of the switching part SL is connected to the electrode part E1. In other words, in the process of changing from the state in FIG. 7 to the state in FIG. 8, the switching part SL releases the connection with the electrode part E0, and is connected to the electrode part E1. When the contact part B of the switching part SL is switched to be connected to the electrode part E1, the switching part SL switches the temperature sensor to be connected to the conversion part CTL from the temperature sensor TC0 to the temperature sensor TC1.

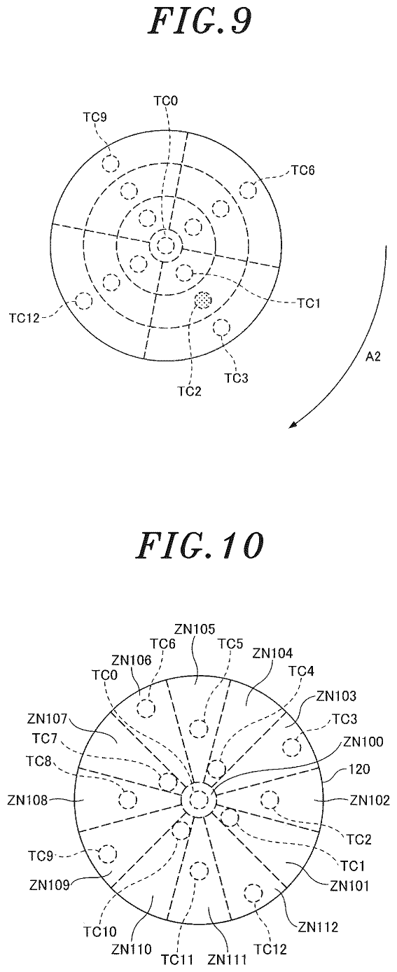

Further, as indicated by an arrow A2 in FIG. 9, when the stage 20 is rotated in a clockwise direction by an angle of 60 degrees from the state in FIG. 7, the contact part B of the switching part SL is connected to the electrode E2. In other words, in the process of changing from the state in FIG. 8 to the state in FIG. 9, the switching part SL releases the connection with the electrode part E1, and is connected to the electrode part E2. By switching the contact part B of the switching part SL to be connected to the electrode part E2, the switching part SL switches the temperature sensor to be connected to the conversion part CTL from the temperature sensor TC1 to the temperature sensor TC2.

As described above, the switching part SL switches the temperature sensor to be connected to the conversion part CTL.

Further, by using the substrate processing apparatus according to the first embodiment, the temperature on the stage can be monitored. In other words, by using the substrate processing apparatus according to the first embodiment, it is possible to perform a temperature monitoring method including a process of switching the plurality of temperature sensors and a process of measuring a temperature using any one of the switched plurality of temperature sensors.

The substrate processing apparatus according to the first embodiment can measure temperatures at multiple locations on the stage that is rotating.

In accordance with the substrate processing apparatus according to the first embodiment, the switching can be performed using one contact part. Therefore, a temperature at one location is measured using a slip ring, the brush of the slip ring can be used as the contact part.

### Second Embodiment

A substrate processing apparatus according to a second embodiment is different from the substrate processing apparatus according to the first embodiment in the arrangement of temperature sensors.

The substrate processing apparatus according to the second embodiment will be described in detail with reference to the drawings. The arrangement of temperature sensors and temperature measurement zones on the stage of the substrate processing apparatus according to the second embodiment will be described. FIG. 10 is a plan view schematically showing the arrangement of temperature sensors and measurement zones on the stage 120 of the substrate processing apparatus according to the second embodiment.

The substrate processing apparatus according to the second embodiment has a plurality of temperature sensors, specifically, thirteen temperature sensors in total, on the stage 120. More specifically, the substrate processing apparatus according to the second embodiment includes the temperature sensors TC0 to TC12. The plurality of temperature sensors are arranged on the stage 120 in a distributed manner.

The substrate processing apparatus according to the second embodiment includes the electrode parts E0 to E12 corresponding to the temperature sensors TC0 to TC12, respectively, similarly to the substrate processing apparatus 1 that is an example of the substrate processing apparatus according to the first embodiment. The temperature sensor TC0 is connected to the electrode part E0. Similarly, the temperature sensors TC1 to TC12 are connected to the corresponding electrode parts E1 to E12.

The substrate processing apparatus according to the second embodiment includes the temperature sensor TC0 at the center of the stage 120 in FIG. 10. The substrate processing apparatus according to the second embodiment has a measurement zone ZN100 around the temperature sensor TC0 on the stage 20. The temperature sensor TC0 measures the temperature in the measurement zone ZN100. The measurement zone ZN100 has a circular shape in plan view.

The substrate processing apparatus according to the second embodiment includes measurement zones ZN101 to ZN112 divided in the circumferential direction to correspond to the number of the temperature sensors TC1 to TC12. The temperatures of the temperatures of measurement zones ZN101 to ZN112 are measured by the temperature sensors TC1 to TC12, respectively.

The temperature sensors TC1, TC4, TC7, and TC10 are located substantially at the same distance from the center of stage 120. Similarly, the temperature sensors TC2, TC5, TC8, and TC11 are provided outside the temperature sensors TC1, TC4, TC7, and TC10, and located substantially at the same distance from the center of stage 120. Further, the temperature sensors TC3, TC6, TC9, and TC12 are provided outside the temperature sensors TC2, TC5, TC8, and TC11, and located substantially at the same distance from the center of stage 120.

The temperature sensors TC1 to TC12 are provided at positions shifted in the circumferential direction.

In accordance with the substrate processing apparatus according to the second embodiment, temperatures at multiple locations on the stage that is rotating can be measured. Further, in accordance with the substrate processing apparatus according to the second embodiment, the temperatures at more dispersed locations on the stage can be measured.

### Third Embodiment

A substrate processing apparatus according to a third embodiment further includes a connection part in addition to the configuration of the substrate processing apparatus according to the first embodiment.

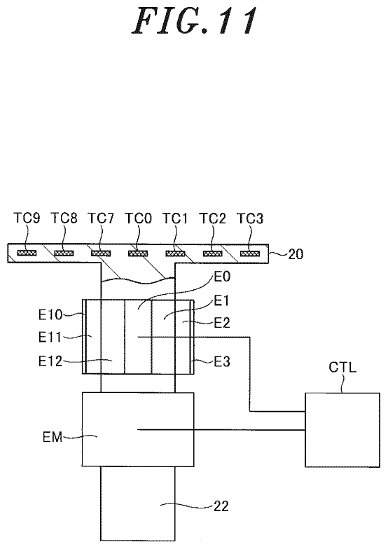

The substrate processing apparatus according to the third embodiment will be described in detail with reference to the drawings. The connection between the temperature sensors and the electrode parts in the substrate processing apparatus according to the third embodiment will be described. FIG. 11 is a partial cross-sectional view schematically showing the arrangement of the electrode parts and a ring electrode part on the stage 20 of the substrate processing apparatus according to the third embodiment.

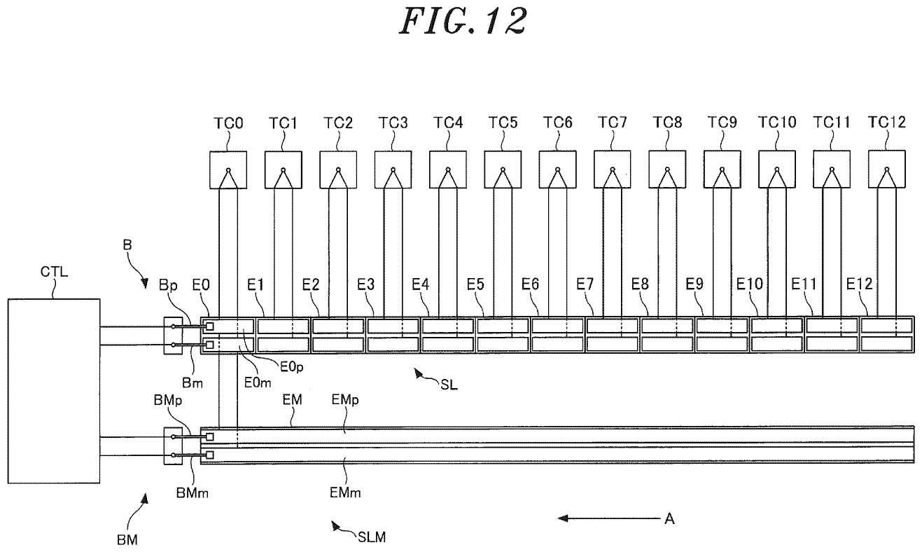

The substrate processing apparatus according to the third embodiment further includes a ring electrode part EM in addition to the configuration of the substrate processing apparatus 1 that is an example of the substrate processing apparatus according to the first embodiment. The connection of the temperature sensors in the substrate processing apparatus according to the third embodiment will be described. FIG. 12 explains the connection of the temperature sensors in the substrate processing apparatus according to the third embodiment.

The connection part SLM includes the ring electrode part EM and a ring contact part BM. The connection part SLM connects the conversion part CTL and the temperature sensor TC0. The connection part SLM is a so-called slip ring. Further, the temperature sensor connected to the connection part SLM is not limited to the temperature sensor TC0. The temperature sensor connected to the connection part SLM may be appropriately selected from the temperature sensors TC1 to TC12.

The ring electrode part EM is provided around the entire circumference in the rotation direction of the stage 20. The ring electrode part EM includes a positive electrode EMp and a negative electrode EMm. The positive electrode EMp and the negative electrode EMm are ring electrodes provided around the entire circumference of the stage 20.

The substrate processing apparatus according to the third embodiment can measure temperatures at multiple locations on the stage that is rotating. Further, the substrate processing apparatus according to the third embodiment can measure temperatures even when the stage is rotating at a high speed.

In the switching part SL, the electrodes are divided in the circumferential direction of the stage 20. Hence, if the stage 20 rotates at a high speed, it may not be possible to measure a temperature. Therefore, by connecting the temperature sensor for measurement using the connection part, the temperature can be measured stably even when the stage 20 is rotating at a high speed without switching the temperature sensor. Further, the substrate processing apparatus according to the second embodiment may also further include the ring electrode part EM.

It should be noted that the substrate processing apparatus according to the embodiment of the present disclosure is are illustrative in all respects and are not restrictive. The above-described embodiment can be changed and modified in various forms without departing from the scope of the appended claims and the gist thereof. The above-described embodiment may include other configurations without contradicting each other, and may be combined without contradicting each other.

1. A substrate processing apparatus comprising:
a rotatable stage;
a plurality of temperature sensors arranged on the stage in a distributed manner;
a conversion part that processes signals outputted from each of the plurality of temperature sensors; and
a switching part that switches the temperature sensor connected to the conversion part,
the switching part includes:
a plurality of electrode parts having electrodes, that are provided in one-to-one correspondence with the plurality of temperature sensors, arranged side by side along a rotation direction of the stage, and connected to the respective corresponding temperature sensors; and
a contact part having a contactor, that is fixed to the stage, brought into contact with the electrode of one of the plurality of electrode parts at a time, and connected to the conversion part.

2. The substrate processing apparatus of claim 1, wherein each of the plurality of temperature sensors includes a positive wiring and a negative wiring,
each of the plurality of electrode parts includes, as the electrode, a positive electrode connected to the positive wiring of a first temperature sensor that is one of the plurality of temperature sensors, and a negative electrode connected to the negative wiring of the first temperature sensor, and
the contact part includes, as the contactor, a positive contactor in contact with the positive electrode of a first electrode part that is one of the plurality of electrode parts, and a negative contactor in contact with the negative electrode connected to the negative wiring of the first electrode part.

3. The substrate processing apparatus of claim 1, further comprising:
a connection part,
wherein the connection part includes:
a ring electrode part including a ring electrode, that is provided around an entire circumference of the stage in a circumferential direction and connected to one of the plurality of temperature sensors, and
a ring contact part including a ring contactor that is in contact with the ring electrode and connected to the conversion part.

4. The substrate processing apparatus of claim 1, wherein each of the plurality of temperature sensors is a thermocouple.

5. The substrate processing apparatus of claim 2, wherein each of the plurality of temperature sensors is a thermocouple.

6. The substrate processing apparatus of claim 3, wherein each of the plurality of temperature sensors is a thermocouple.

7. A temperature monitoring method in a substrate processing apparatus having a rotating stage, comprising:
switching between a plurality of temperature sensors by connecting a contactor to one of a plurality of electrodes, the electrodes being provided in one-to-one correspondence with the plurality of temperature sensors arranged on the stage in a distributed manner, arranged side by side along a rotation direction of the stage, and connected to the respective corresponding temperature sensors, the contactor being fixed to the stage and brought into contact with one of the plurality of electrodes at a time; and
measuring a temperature using one of the plurality of temperature sensors after switching.
